(19) United States
(12) Patent Application Publication
(10) Pub. No.: US 2022/0102935 A1
(43) Pub. Date: Mar. 31, 2022

(54) SEMICONDUCTOR DEVICE AND FABRICATION METHOD

(71) Applicant: UCL BUSINESS PLC, London (GB)

(72) Inventors: Siming CHEN, London (GB); Mengya LIAO, London (GB); Suguo HUO, London (GB); Mingchu TANG, London (GB); Jiang WU, Londong (GB); Alwyn SEEDS, London (GB); Huiyun LIU, London (GB)

(21) Appl. No.: 17/450,002

(22) Filed: Oct. 5, 2021

Related U.S. Application Data
(63) Continuation of application No. 16/481,488, filed on Jul. 29, 2019, now abandoned.

(30) Foreign Application Priority Data
Jan. 30, 2017 (GB) 1701488.7

(51) Int. Cl. H01S 5/02; H01L 33/00; H01S 5/10; H01S 5/12; H01S 5/30; H01S 5/34; H01S 5/343

(52) U.S. Cl. CPC H01S 5/021; H01L 33/0045; H01S 5/0203; H01S 5/1085; H01S 2301/173; H01S 5/3013; H01S 5/3412; H01S 5/34313; H01S 5/12

(57) ABSTRACT

Disclosed herein is a semiconductor device comprising: a silicon substrate; a germanium layer; and a buffer layer comprised of at least one layer of III-V compound, formed directly on silicon; at least one layer containing III-V compound quantum dots wherein one or more facets are formed using focused ion beam etching such that the angle between the plane of the facet is normal to the plane of growth.

### RELATED APPLICATIONS

The present application is a Continuation of U.S. application Ser. No. 16/481,488 filed Jul. 29, 2019, which is a National Phase of International Application Number PCT/GB2018/050259 filed Jan. 30, 2018, and claims priority to Great Britain Application Number 1701488.7 filed Jan. 30, 2017, the disclosures of which are hereby incorporated by reference herein in their entireties.

### FIELD

The present invention relates to a III-V semiconductor device, in particular relating to III-V compounds grown on silicon (Si) and to structures that can provide reproducible, high yield and controlled facet reflectivity.

### BACKGROUND

Over the last few years, an almost exponential growth in global internet traffic imposes significant challenges on modern Datacom industry which requires an efficient interconnection framework that supports large bandwidth demand and low power consumption. These harsh requirements created a major “bottleneck” for conventional copper interconnections in transporting digital information on difference scales, ranging from worldwide links to inter- and intra-chip communications. The integration of optical interconnects with photonic integrated circuits (PICs) on silicon platform has become one of the most promising candidates to solve this problem. There have also been suggestions to achieve large bandwidth through integrating wavelength division multiplexing (WDM) systems into the PICs. This has traditionally been done by combining an array of laser diodes (LDs) emitting at different wavelengths. Recently, broadband sources, such as superluminescent light-emitting diodes (SLDs) have attracted tremendous attention for applications in WDM systems. By utilizing the spectrum-slicing technique, broad emission spectrum from a single broadband source can be ‘sliced’ into many different wavelengths to satisfy all the required channels, therefore the number of active components on PICs can be significantly reduced leading to lower power/heat consumption. And this is one of the major advantages of SLDs over LDs and other competitors for use in WDM systems. To fully exploit the economies of scale of silicon manufacturing environments, and to achieve low-cost, massive scalable integration, development of COMS compatible Si-based light sources is of considerable importance. But Si, like Ge, is an indirect bandgap material, and is naturally an inefficient emitter. Monolithic growth of high quality III-V material on Si, and then fabricate electrically pumped continuous-wave (c.w.) Si-based light sources using CMOS-compatible wafer-scale processing methods is seen as one of the most promising alternatives. But the large material dissimilarity between III-Vs and group IV materials is a severe obstacle. The superiority of quantum dot (QD) structures for achieving broad bandwidth in broadband sources is well established owning to their naturally large size inhomogeneity when grown by the S-K growth mode, and recently, the use of QDs as active region has also shown their advantages for monolithic growth of III-V lasers on Ge, Ge-on-Si, and Si substrates due to their reduced sensitivity to defects and their delta-function density of state.

We have shown in the patent, {U.S. Pat. No. 9,343,874 (B2)} that the use of an AlAs nucleation layer prior to the growth of the III-V layer on Si can enable a successful electrically pumped laser to be grown on Si. We have also shown in patent {U.S. Pat. No. 9,401,404 (B2)} that the use of Ge on Si as the substrate upon which the III-V layer is grown can enable a successful electrically pumped laser to be grown on Si.

Both approaches mentioned above have used offcut substrates, i.e. Si (001) or equivalent orientation wafers with an offcut of 4° to the [110] plane and Ge (001) wafers with an offcut of 6° to the [110] plane, in order to prevent the formation of antiphase domains (APDs) while growing polar III-V materials on non-polar group-IV substrates. Although this approach is successful in overcoming the APD problem, it has experienced difficulties in producing satisfactory facets for an optical device on Si. Facet cleaving {H. Liu, T. Wang, Q. Jiang, R. Hogg, F. Tutu, F. Pozzi, and A. Seeds. Long-wavelength InAs/GaAs quantum-dot laser diode monolithically grown on Ge substrate, Nature Photonics 5 (2011); S. Chen, W. Li, J. Wu, Q. Jiang, M. Tang, S. Shutts, S. Elliott, A. Sobiesierski, A. Seeds, I. Ross, P. Smowton, and H. Liu. Electrically pumped continuous-wave III-V quantum dot lasers on silicon, 10 (2016)} and polishing {A. Liu, C. Zhang, J. Norman, A. Snyder, D. Lubyshev, J. Fastenau, A. Liu, A. Gossard, and J. Bowers. High performance continuous wave 1.3 μm quantum dot lasers on silicon, Appl. Phys. Lett. 104 (2014); A. Liu, IEEE, R. Herrick, O. Ueda, P. Petroff, A. Gossard, and J. Bowers. Reliability of InAs/GaAs Quantum Dot Lasers Epitaxially Grown on Silicon, IEEE J. Sel. Topics in Quant. Electron. 21 (2015)} have been previously used to overcome this problem, while these techniques still suffer from issues related to poor yield and poor device lifetime. Moreover, for monolithic photonic integration, the formation of reflective mirrors by either approach will be unpractical; it therefore calls for an etching technique, which can post-fabricate cavity facets without sophisticated re-growth and additional etching processes.

Among these approaches, focused ion beam (FIB) milling has been considered as one of the most rapid and flexible techniques, due to its unique capability of photoresist-free and direct writing, to create 3D regulated patterns ranging from micro- to nanometre scale. As a result, FIB milling has been widely employed to etch facets and to adjust facet reflectivity of light sources on InP- and GaN-based substrates {L. Bach, S. Rennon, J. P. Reithmaier, Member, IEEE, A. Forchel, J. L. Gentner, and L. Goldstein. Laterally Coupled DBR Laser Emitting at 1.55 μm Fabricated by Focused Ion Beam Lithography, IEEE Photon. Technol. Lett. 14, (2002); F. Vallini, D. S. L. Figueira, P. F. Jarschel, L. A. M. Barea, A. A. G. Von Zuben, and N. C. Frateschi. Effects of Ga+ milling on InGaAsP quantum well laser with mirrors milled by focused ion beam. J. Vac. Sci. Technol. B 27 (2009); M. P. Mack, G. D. Via, A. C. Abare, M. Hansen, P. Kozodoy, S. Keller, J. S. Speck, U.K. Mishra, L. A. Coldren and S. P. DenBaars. Improvement of GaN-based laser diode facets by FIB polishing, Electron. Lett. 34 (1998); H. Katoh, T. Takeuchi, C. Anbe, R. Mizumoto, S. Yamaguchi, C. Wetzel, H. Amano, I. Akasaki, Y. Kaneko and N. Yamada. GaN Based Laser Diode with Focused Ion Beam Etched Mirrors, Jpn. J. Appl. Phys. 37 (1998)}. In addition, FIB has been used to etch facets of an InGaAs QD laser grown on Si with QD dislocation filter layers (DFLs) {J. Yang, P. Bhattacharya, and Zhuang Wu. Monolithic Integration of InGaAs—GaAs Quantum-Dot Laser and Quantum-Well Electroabsorption Modulator on Silicon, IEEE Photon. Technol. Lett. 19 (2007)}.

There is a general need to improve known techniques.

### SUMMARY OF INVENTION

Embodiments provide post-fabrication processed diverse Si-based III-V QD light sources where the facet reflectivity is controlled in a reproducible and high yield way by means of FIB. Embodiments achieve reasonable room temperature (RT) continuous-wave (c.w.) lasing characteristics from InAs/GaAs QD laser grown on Si with FIB-made front facet. Effectively reduced facet reflectivity is achieved from angled facet devices, by focused Ge ion beam milling of the front facet of the edge emitting Si-based InAs/GaAs QD laser, allowing the InAs/GaAs QD superluminescent light-emitting diodes (SLDs) operating under c.w. mode to be realized for the first time at room temperature.

According to a first aspect of the invention, there is provided a semiconductor device comprising: a silicon substrate; a germanium layer a buffer layer comprised of at least one layer of III-V compound, formed directly on silicon; at least one layer containing III-V compound quantum dots wherein one or more facets are formed using focused ion beam etching such that the angle between the plane of the facet is normal to the plane of growth.

According to a second aspect of the invention, there is provided a semiconductor device comprising: a silicon substrate; a buffer layer comprised of at least one layer of III-V compound, formed directly on silicon; one or more strained layer superlattices; at least one layer containing III-V compound quantum dots; wherein one or more facets are formed using focused ion beam etching such that the angle between the plane of the facet is normal to the plane of growth.

Preferably, ions of the focused ion beam include positive ions of He, Ne, and Ga.

Preferably, the probe current is less or equal to 500 pA.

Preferably, the step size is less or equal to 100 nm.

Preferably, the dwell time is less or equal to 1 ms.

Preferably, the angle between the plane of the facet and the normal in the growth plane to the axis of a waveguide forming part of the device (the facet angle) is chosen to create cavity mirrors with different angles so that the facet reflectivity can be controlled in a reproducible and high yield way to create diverse semiconductor devices on silicon.

Preferably, the facet angle is a value between 0 degrees and 20 degrees.

According to a third aspect of the invention, there is provided a laser or a superluminescent light emitting diode using the structure of any previous aspect.

Preferably, the facet angle is in the range 0 degrees to 5 degrees.

Preferably, the facet angle varies from 6 degrees to 13 degrees.

Preferably, there is a waveguide forming part of the device incorporates a Distributed Feedback (DFB) grating.

Preferably, there is a waveguide forming part of the device incorporating one or more Distributed Bragg Reflector (DBR) gratings.

### LIST OF FIGURES

Embodiments of the invention will now be described, by way of example only, with reference to the accompanying drawings in which:

FIG. 1A is a schematic diagram of InAs QD laser structure grown on Si substrates;

FIG. 1B is a top view of the schematic diagram of the fabricated laser structure. The top-left SEM image shows the typical FIB-made (top-view) front facet of Si-based InAs QD laser. The Bottom-right cross-sectional SEM image shows the typical as-cleaved back facet of the Si-based InAs QD laser;

FIG. 2 is a graph that shows LIV characteristics for Si-based InAs/GaAs QD laser with FIB-made facet and as-cleaved facets measured under c.w. operation at room temperature. The inset shows the typical SEM image of FIB-made front facet of Si-based InAs QD laser;

FIGS. 3A and 3B are graphs that show Si-based device characterization. FIG. 3A shows L-I characteristics for a 25 μm×3000 μm Si-based InAs/GaAs QD devices with different front facet angles of 0°, 5°, 8°, 10°, 13°, and 16°, under c.w. operation at room temperature. The inset (left) shows the L-I characteristics for this Si-based InAs/GaAs SLD laser with 8o FIB-made angled facet under pulsed operation (1% duty-cycle and 1 μs pulse width) at room temperature. The inset (right) shows a cross-sectional SEM image of Si-based InAs/GaAs QD laser with 8o angled front facet. FIG. 3B shows room temperature EL spectra for Si-based QD devices with different front facet angles of 5°, 8°, 10°, and 13° at various c.w. injection currents. Magnetization as a function of applied field;

FIG. 4 is a graph that shows the measured full-width-at-half-maximum (FWHM) for devices with 5° and 8° facet angles as a function of injection current. In t-inset shows the evolution of the peak wavelength (measured at 300 mA) for Si-based QD devices versus the etched facet angle;

FIG. 5 is a graph that shows the comparison between measured L-I characteristics and simulation results by rate equations; and

FIG. 6 is a graph that shows the calculated facet reflectivity and the effective facet reflectivity as a function facet angle.

FIG. 7 is a schematic diagram of InAs QD laser structure grown on Ge layer on Si substrates.

### DESCRIPTION OF EMBODIMENTS

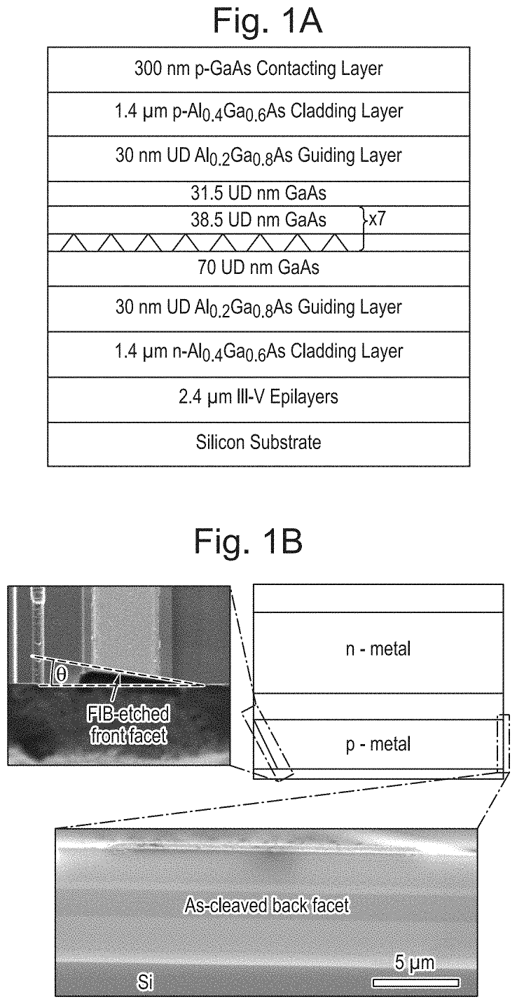

In one exemplary embodiment of the present invention, as shown, the InAs/GaAs QD laser structure (as shown in FIG. 1A) is, except for the growth of active region, nominally identical to that of laser structure described in {S. Chen, W. Li, J. Wu, Q. Jiang, M. Tang, S. Shutts, S. Elliott, A. Sobiesierski, A. Seeds, I. Ross, P. Smowton, and H. Liu. Electrically pumped continuous-wave III-V quantum dot lasers on silicon, Nature Photonics 10 (2016)}, the entire contents of which are incorporated herein by reference. Here, in order to improve the modal gain, 7 dot-in-well (DWELL) layers have been used. After completing the growth of laser structure, broad-area lasers were fabricated and then mounted on copper heat-sinks and gold-wire-bonded to enable testing. After device characterization for laser with as-cleaved facets was completed, the front as-cleaved facet was then being milled, (with the back as-cleaved facet remains unchanged), by focused Ga ion beam to form FIB-made front angled facet with different angles of 0°, 5°, 8°, 10°, 13°, and 16°, respectively as illustrated by FIG. 1B.

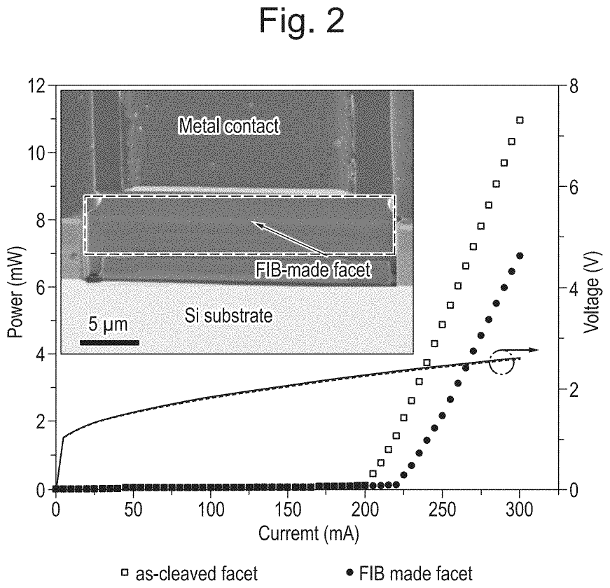

FIG. 2 compares the light-current-voltage (LIV) characteristics for a InAs/GaAs QD laser grown on Si with FIB-made facet and a conventional device with as-cleaved facets under RT c.w. operation. The measured series resistance extrapolated from I-V curves were very similar between those two laser devices. The measured threshold current and slope efficiency are 200 mA and 0.125 W/A, respectively for the as-cleaved Si-based laser, and 222 mA and 0.095 W/A for the Si-based laser with FIB-made facet. Compared with as-cleaved facets device, there is no significant degeneration of device performance for Si-based laser with FIB-made facet. It should be mentioned that, the results presented for as-cleaved lasers represent the particular situation, that the facets were perfectly cleaved. However, in general, the offcut silicon substrates do not cleave smoothly along [110] plane, leading to imperfect cleaved mirrors and poor yield.

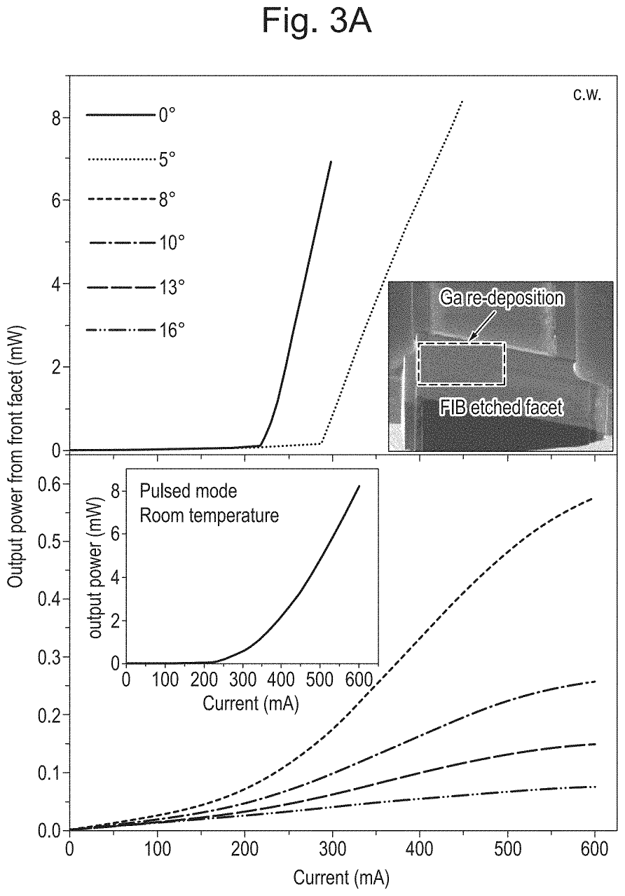

FIG. 3A shows the RT c.w. L-I characteristics for Si-based InAs/GaAs QD devices with different front facet angles of 0°, 5°, 8°, 10°, 13°, and 16°, respectively. The threshold current of the Si-based laser with a 0° front facet angle is 222 mA. By increasing the etched angle from 0° to 5°, the threshold current is increased to 280 mA, and this is due to the effectively reduced reflectivity from the angled facet, where the light beam being coupled back into guided modes has been reduced. But still the device exhibited a typical lasing characteristics. Increasing etched facet angle to 8°, a typical superluminescent behaviour evidenced by the superliner increase in output power with increasing current is observed. The maximum RT c.w. output power measured from the front angled facet is 0.56 mW at 600 mA, where a power saturation due to over-heating of the device is observed. This Si-based QD SLD has also been examined under pulsed operation as seen in the inset (left-side) of FIG. 3(a), with limited self-heating, an output power of over 8 mW has been obtained at 600 mA where no power saturation observed up to this current injection. With further increasing the etched facet angle to 13°, it is noted that a nominal LED-like L-I characteristics is observed.

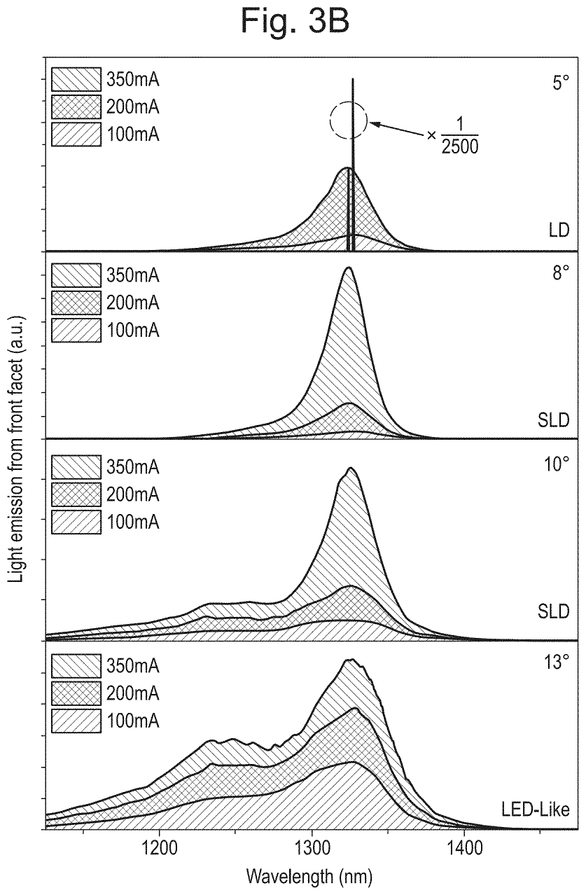

FIG. 3B shows RT electroluminescence (EL) spectra for Si-based QD devices with different front facet angles of 5°, 8°, 10°, and 13° at various c.w. injection currents. The measured full-width at half maximum (FWHM) for devices with 5° and 8° facet angle as a function of injection current are summarized in the FIG. 4. As seen for the device with 5° facet angle, at a low injection of 100 mA, a broad spontaneous emission from the ground state of QDs with a FWHM of 52.5 nm is obtained, as the current increases to 300 mA, the emission peak increases suddenly in intensity and the FWHM narrows sharply to only ˜2.4 nm, which indicates that lasing oscillation can still be achieved from this device despite the effectively reduced facet reflectivity from the 5° angled front facet. In contrast, for device with 8° facet angle, the measured FWHM narrows slightly with increasing injection up to 600 mA, which suggests that lasing has been fully inhibited in this device, and the observed spectrum narrowing effect is because: when the device working as a SLD, the model gain is larger than the internal loss within the certain frequency range in the middle of the gain spectrum. The spectrum is therefore dominated by the ASE within this frequency range. Towards the edge of the gain spectrum, the frequency-dependent gain decreases and those parts of the spectrum are dominated by spontaneous emission. The spectrum narrowing is an indirect indication of the existence of ASE. Similar amplified spontaneous emission has also been observed from the device with 10° facet angle. As seen from the EL spectrum for device with 13° facet angle, a linear increase in spontaneous emission peak intensity with increasing current is observed, representing a nominal LED behavior (although the spectrum is still governed by ASE) due to the completely suppressed optical feedback within the FP resonator.

The evolution of the peak wavelength (measured at 300 mA) for Si-based QD devices versus the etched facet angle is summarized in the inset of FIG. 4. It is clear to see that the peak wavelength for Si-based QD devices with different front facet angles was almost unchanged with a value of ˜1326 nm, despite the fact that device characteristics with different facet angles have been significantly modified, which indicates that FIB technology is a promising tool with large flexibility to directly post-fabricate active photonic devices while maintaining desired commutation wavelengths.

We developed a simple rate equation model to gain further insight into the suppression of the laser oscillation using angled facets. The carrier and photon dynamics is described by the following equations

$$\begin{matrix}\frac{d N}{d t} = {η}_{i} \frac{I}{qV} - ( A N + B {N}^{2} + C {N}^{3} ) - {v}_{g} Γ g {N}_{p} & ( 1 ) \\ \frac{d {N}_{p}}{d t} = {v}_{g} Γ g {N}_{p} + β B {N}^{2} - {v}_{g} ( {α}_{i} + {α}_{m}^{′} ) {N}_{p} & ( 2 )\end{matrix}$$

where N and Nₚ are the carrier and photon densities respectively, A is the defect recombination coefficient, B is the spontaneous emission coefficient, C is the Auger recombination coefficient, Γ is the optical confinement factor, v_{g} is group velocity of light, V is the volume of the active region, ηᵢ is the internal efficiency, αᵢ is the internal optical loss, and β is the spontaneous emission factor. Here we adopt two different definitions of the mirror loss:

$$\begin{matrix}{α}_{m} = \frac{1}{2 L} ln ( \frac{1}{{R}_{1} {R}_{2}} ) \\ and & ( 3 ) \\ {α}_{m}^{′} = \frac{1}{2 L} ln ( \frac{1}{{R}_{1} {R}_{2}^{′}} ) & ( 4 )\end{matrix}$$

the latter is called the effective mirror loss, where L is the device length, R₁ is the reflectivity of the back facet, R₂ is the reflectivity of the front (angled) facet, and R′₂ is the effective reflectivity of the front facet taking into account the coupling factor between the reflected light from the front facet and guided modes of the ridge waveguide. We assume the material gain linearly depends on the carrier density by ignoring the excessively complicated gain saturation process in SLEDs. By self-consistent iteration method the rate equations can be numerically solved, yielding an output power from the front facet

$${P}_{0} = {v}_{g} {α}_{m}^{′} hv {V}_{p} {N}_{p} \cdot \frac{\frac{1}{\sqrt{{R}_{2}}} - \sqrt{{R}_{2}}}{\frac{1}{\sqrt{{R}_{2}}} - \sqrt{{R}_{2}} + \frac{1}{\sqrt{{R}_{1}}} - \sqrt{{R}_{1}}} . \qquad ( 5 )$$

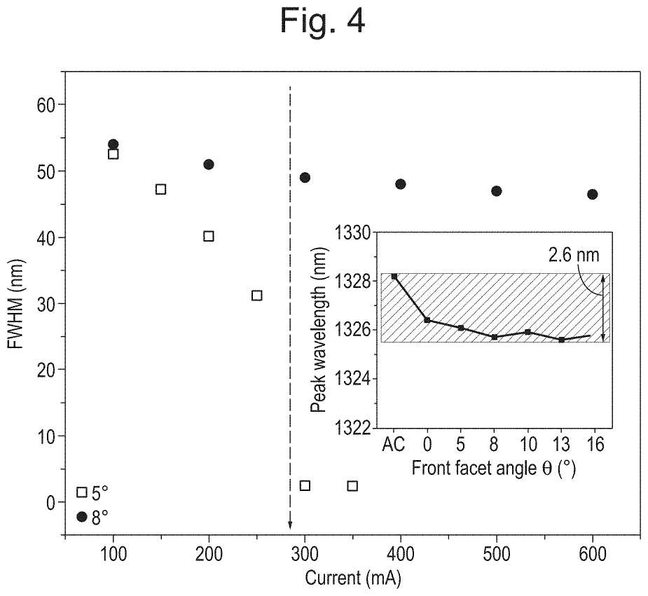

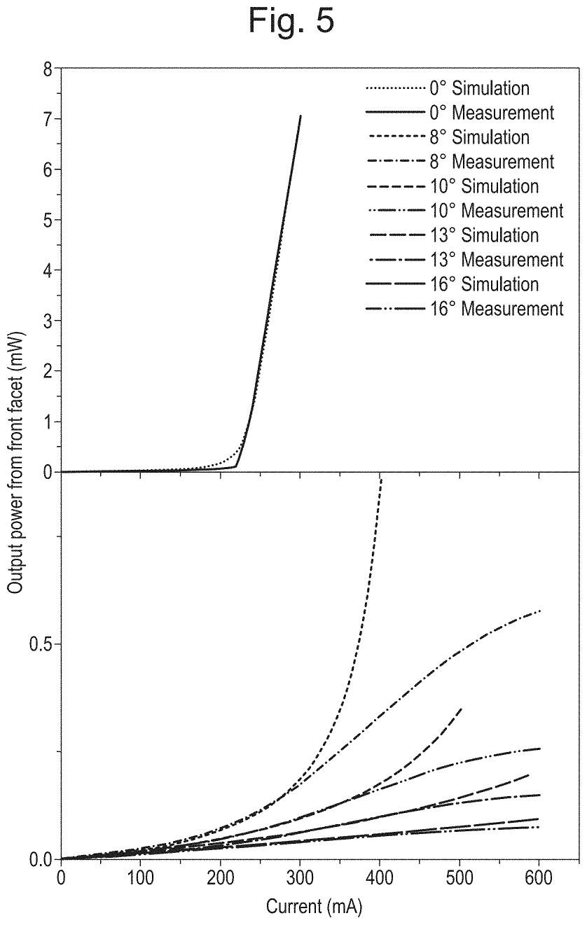

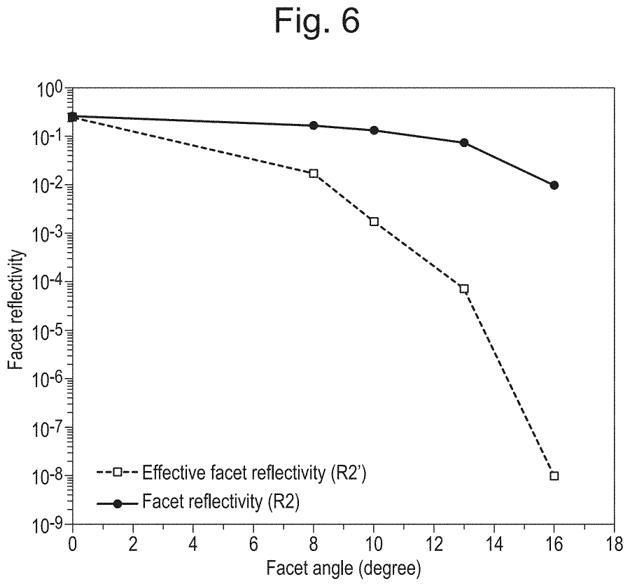

FIG. 5 shows the comparison between measured L-I characteristics and simulated results by rate equations. The agreement between measurement data and simulated results is reasonably good for all facet angles at low injection levels. The obvious mismatch between the simulation and experimental results above 300 mA are due to the complicated thermal effects in SLEDs, which lead to severer degradation of the material gain at high injection. The angle dependence of R₂ is calculated using Fresnel equations based on a simple assumption of ray optics, as shown by the curve in FIG. 6. During the simulation, we have only optimized the value of R′₂ to obtain the best fitting results. FIG. 6 plots R′₂ as a function of the facet angle, in which each of the R′₂ values correspond to one of the fitting curves in FIG. 5. The increased difference between R₂ and R′₂ suggests the coupling factor to guided modes is significant reduced with increasing facet angles, which contributes to the suppression of lasing.

These results have demonstrated the use of FIB for developing diverse light sources grown on Si in a reproducible and high yield way, indicating that FIB technique is very promising for post-fabricating integrated light sources on Si platform for Si photonics in a rapid and simple single-step.

Detailed methods of embodiments are described below.

Crystal growth: The InAs/GaAs QD laser structure was directly grown on phosphorus-doped Si substrates by a solid-source molecular beam epitaxy (MBE) system. The (001)-silicon wafer with 4° miscut-angle misoriented towards the [011] plane was used to suppress the antiphase boundaries (APBs). Before the initial epitaxy growth, oxide desorption was performed by thermally treating the silicon substrate at 900° C. for 30 mins, which followed by depositing III-V epilayers that consist of a 6 nm AlAs nucleation layer grown by migration-enhanced epitaxy (MEE), 600 nm GaAs buffer formed by a three-step temperature growth technique and InGaAs/GaAs strained layer superlattices (SLSs). Above the III-V buffer, a standard p-i-n laser structure was deposited in the following order: a 1.4 μm n-doped AlGaAs cladding layer, a 30 nm lower undoped AlGaAs guiding layer, a five-layer InAs/InGaAs/GaAs dots-in-well (DWELL) active region, a 30 nm undoped upper AlGaAs guiding layer, a 1.4 μm p-doped AlGaAs cladding layer, and finally a 300 nm highly p-doped GaAs contacting layer.

Device Fabrication: The Si-based QD laser structure was firstly fabricated into broad-area lasers with varying stripe widths of 25 μm and 50 μm following standard optical lithography and wet chemical etching techniques. The top mesa was etched to about 100 nm above the active region. The top n-contact layer was etched down to the highly n-doped GaAs buffer layer just below the n-type AlGaAs cladding layer. Ti/Pt/Au and Ni/GeAu/Ni/Au were deposited on top of the etch mesa and exposed highly n-doped GaAs buffer layer to form the p- and n-contacts, respectively. After thinning the silicon substrate to 120 μm, the laser bars were cleaved into the desired cavity lengths, which were then mounted on copper heatsinks and gold-wire bonded to enable testing. The final devices described here were 25 μm in width and 3 mm in length, and no facet coatings were applied.

Post-Device Fabrication: After device characterization for laser with as-cleaved facets was completed, the front as-cleaved facet was then being milled, (with the back as-cleaved facet remains unchanged), by focused Ge ion beam to form FIB-made front angled facet with different angles of 0°, 5°, 8°, 10°, 13°, and 16°, respectively.

Measurements: The FIB milling was performed using a Zeiss XB 1540 “cross beam” FIB microscope with a probe current of 500 pA, a step size of 50 nm and a dwell time of 0.5 ms. Characteristics were measured under both cw and pulsed conditions of 1 μs pulse-width and 1% duty-cycle.

Other embodiments are described below.

Three key parameters for focused Ga+ ion beam milling are probe current, step size and dwell time. In the earlier described embodiments of the invention, although a probe current of 500 pA, a step size of 50 nm and a dwell time of 0.5 ms has been used, these parameters may be varied according to the requirement to the facet quality. For example, optionally, a smaller probe current can be used, the facet quality can be improved.

In the earlier described embodiments of the invention, Ge ion beam has been used to etch/polish the cavity mirrors. However, any suitable ion beam could be used. Optionally, Ne⁺ ion beam or He⁺ ion beam can be used, and the facet quality can be improved.

This invention is not limited to etch facets of a Fabry-Perot (FP) resonator to form a FP laser grown on silicon substrates, but could be used for the fabrication of distributed feedback (DFB) gratings and distributed Bragg Reflector (DBR) gratings, so as to form a DFB or a DBR laser grown on silicon substrates.

The invention is not limited to a laser or a SLD on a Si substrate, but could be used for other general semiconductor structures, for example semiconductor optical amplifiers (SOAs), detectors, modulators or other III-V photonic devices on a Si substrate. III-V electronic devices, such as diodes and transistors could also be fabricated with the use of this invention. Applications include but are not limited to chip-to-chip optical inter-connects, solar cells, optical fibre communications (light emitters and detectors).

Other embodiments of the invention will be apparent to those skilled in the art from consideration of the specification and practice of the embodiments disclosed herein. It is intended that the specification and examples be considered as exemplary only, with a true scope and spirit of the invention being indicated by the following claims. In addition, where this application has listed the steps of a method or procedure in a specific order, it may be possible, or even expedient in certain circumstances, to change the order in which some steps are performed, and it is intended that the particular steps of the method or procedure claims set forth here below not be construed as being order-specific unless such order specificity is expressly stated in the claim.

1. A semiconductor device comprising:
a silicon substrate;
a germanium layer;
a buffer layer comprised of at least one layer of III-V compound, formed directly on silicon; and
at least one layer containing III-V compound quantum dots,
wherein one or more facets are formed using focused ion beam etching such that an angle between a plane of the facet is normal to a plane of growth.

2. A semiconductor device comprising:
a silicon substrate;
a buffer layer comprised of at least one layer of III-V compound, formed directly on silicon;
one or more InGaAs/GaAs strained layer superlattices; and
at least one layer containing III-V compound quantum dots,
wherein one or more facets are formed using focused ion beam etching such that an angle between a plane of the facet is normal to a plane of growth.

3. The device of claim 1, wherein ions of the focused ion beam include positive ions of He, Ne, and Ga.

4. The device of claim 1, wherein probe current is less or equal to 500 pA.

5. The device of claim 1, wherein step size is less or equal to 100 nm.

6. The device of claim 1, wherein dwell time is less or equal to 1 ms.

7. The device of claim 1, wherein the angle between the plane of the facet and the normal in the growth plane to an axis of a waveguide forming part of the device, which is a facet angle, is chosen to create cavity mirrors with different angles so that a facet reflectivity can be controlled in a reproducible and high yield way to create diverse semiconductor devices on silicon.

8. The device of claim 7, wherein the facet angle is a value between 0 degrees and 20 degrees.

9. A laser or a superluminescent light emitting diode using the structure of claim 7.

10. The laser of claim 9, wherein the facet angle is in a range from 0 degrees to 5 degrees.

11. The superluminescent light emitting diode of claim 9, wherein the facet angle varies from 6 degrees to 13 degrees.

12. The device of claim 1, further comprising a waveguide forming part incorporating a Distributed Feedback (DFB) grating.

13. The device of claim 1, further comprising a waveguide forming part incorporating one or more Distributed Bragg Reflector (DBR) gratings.

14. A semiconductor device comprising:
a silicon substrate;
a germanium layer;
a buffer layer comprised of at least one layer of III-V compound, formed directly on the germanium layer; and
at least one layer containing III-V compound quantum dots,
wherein one or more facets are formed using focused ion beam etching such that an angle between a plane of the facet is normal to a plane of growth.
